(19) United States
(12) Patent Application Publication
(10) Pub. No.: US 2015/0076620 A1
(43) Pub. Date: Mar. 19, 2015

(54) METHOD FOR MANUFACTURING TRANSISTORS AND ASSOCIATED SUBSTRATE

(71) Applicant: IMEC VZW, Leuven (BE)

(72) Inventors: Niamh WALDRON, Leuven (BE); Liesbeth WITTERS, Linden (BE)

(21) Appl. No.: 14/484,070

(22) Filed: Sep. 11, 2014

(30) Foreign Application Priority Data
Sep. 11, 2013 (EP) 13183985.4

(51) Int. Cl. H01L 27/092; H01L 29/267; H01L 21/762; H01L 29/04; H01L 21/8238; H01L 29/06; H01L 29/20; H01L 29/161

(52) U.S. Cl. CPC H01L 27/0922; H01L 29/20; H01L 29/267; H01L 29/161; H01L 29/045; H01L 21/823807; H01L 21/823878; H01L 29/0653; H01L 21/762
USPC 257/401; 438/285

(57) ABSTRACT

The disclosed technology generally relates to semiconductor devices, and more particularly to different types of transistors having different channel materials. In one aspect, a method of fabricating a semiconductor device includes providing a substrate comprising a silicon substrate having a main surface oriented in a {100} crystal plane and having a notch oriented in a <100> direction. The method additionally includes forming a plurality of silicon protrusions in a first predetermined region by recessing portions of the main surface surrounding the silicon protrusions. The method additionally includes forming shallow trench isolation (STI) structures adjacent to the silicon protrusions to electrically isolate the silicon protrusions, thereby defining channel areas of a transistor of a first type. The method further includes removing at least upper portions of the silicon protrusions, thereby forming trenches between neighboring STI structures and filling the trenches with a III-V material.

### CROSS-REFERENCE TO RELATED APPLICATIONS

This application claims foreign priority to European patent application EP 13183985.4, filed on Sep. 11, 2013, the content of which is incorporated by reference herein in its entirety.

### BACKGROUND OF THE INVENTION

1. Field of the Invention

The disclosed technology generally relates to semiconductor devices, and more particularly to different types of transistors having different channel materials. The disclosed technology also relates to a method of using the different channel materials having different lattice constants than silicon to form the channels of the different transistor types.

2. Description of the Related Technology

In some semiconductor technologies, different semiconductor materials are used to form channels of different types of transistors on the same silicon substrate. For example, for some complementary metal-oxide semiconductor (CMOS) technologies where high carrier mobilities (μₚ and/or μₙ) are desired, strained or relaxed germanium-based materials can be used to form channels for p-channel transistors (p-FET) and III-V materials can be used to form channels for n-channel transistors (n-FET).

In some technologies, some of the channel materials of the different types of transistors are formed via hetero-epitaxial growth of different channel materials on a single substrate, e.g., a silicon substrate. However, hetero-epitaxial growth often results in strain relaxation of the epitaxially grown channel materials, resulting in dislocation formation due to the difference (mismatch) of lattice parameters of the materials involved.

A solution proposed in literature includes selective growth of semiconductor in narrow oxide trenches, by using the so-called Aspect Ratio Trapping (ART) technique. In the ART technique, most defects are trapped at the bottom of the trenches by using oxide trench sidewalls. The top part of the semiconductor grown in the trench is then strain-relaxed with a relatively low density of defects. An example employing the ART technique is described, for instance, in the patent publication US 2010/0216277.

However, as best understood, the ART technique forms relaxed semiconductors with relatively low density of defects when they are formed in relatively narrow and short trenches. However, for various applications, e.g., advanced logic CMOS devices and photonic devices, relatively long trenches are often desired. Thus, there is a need for forming relatively long heterogeneous channels on silicon substrates with relatively low defect densities.

### SUMMARY OF CERTAIN INVENTIVE ASPECTS

It is an aim of the present disclosure to provide structures and methods for manufacturing semiconductor devices, e.g., CMOS devices, where the CMOS devices include transistor devices of different conductivity types, e.g., n-FET and p-FET devices. The CMOS devices include transistor devices which comprise channel materials which have different lattice constants, and whereby these different lattice constants of the respective channel materials are different from the lattice constant of an underlying silicon substrate, on which the transistor devices are formed.

This aim is achieved according to the disclosure with a method showing the technical characteristics of the first independent claim.

It is a further aim to provide an associated substrate.

This aim is achieved according to the disclosure with the substrate showing the technical characteristics of the second independent claim.

According to an aspect of the present invention, a method for manufacturing a CMOS device comprises: providing a starting substrate, the starting substrate comprising a silicon substrate (or first semiconductor layer) the surface of which is oriented along the {100} crystal plane and the notch of which is oriented along the <100> direction; forming shallow trench isolation structures in a first predetermined region, thereby defining channel areas in the substrate embodied as silicon protrusions extending from the silicon substrate and being isolated from each other by means of the shallow trench isolation structures; removing the silicon protrusions, thereby creating trenches; filling the trenches by epitaxially growing a III-V material in the trenches, to thereby form channel structures of transistors of a first type which are essentially defect-free (for instance having a defect density smaller than 1×10⁵/cm²).

According to an aspect of the present invention, the method comprises providing a starting substrate, the starting substrate comprising a silicon substrate (constituting a first semiconductor layer) the surface of which is oriented along the {100} crystal plane and the notch of which is oriented along the <100> direction; a dielectric bonding layer on top of the surface, and a second semiconductor layer, the second semiconductor layer being bond to the silicon substrate by means of the dielectric bonding layer and having a lattice constant which is different from the lattice constant of the silicon substrate; removing a first portion of the second semiconductor layer and the dielectric bonding layer in a first predetermined region for forming a transistor device of a first type, thereby exposing the underling silicon substrate, and thereby leaving a second portion of the second semiconductor layer (and a corresponding second portion of the dielectric bonding layer) in a second predetermined region for forming a transistor device of a second type; forming shallow trench isolation structures in the first region, thereby defining channel areas in the substrate embodied as silicon protrusions extending from the silicon substrate and being isolated from each other by means of isolation structures; removing the silicon protrusions, thereby creating trenches; filling the trenches by epitaxially growing a III-V material in the trenches, to thereby form channel structures of transistors of a first type which are essentially defect-free; patterning the second semiconductor layer in the second predetermined region, to thereby form channel structures of transistors of a second type.

The respective transistor devices have channel materials which have different lattice constants, and in some embodiments, these different lattice constants of the respective channel materials are different from the lattice constant of the underlying silicon substrate.

The transistor devices of the first and second type are preferably transistor device of the n-type (i.e., n-FET) and of the p-type (i.e., p-FET) respectively, or vice versa.

The first and second predetermined regions are preferably adjacent.

Shallow trench isolation structures are formed in the first predetermined region by patterning, gap-filling, and planarizing.

According to some embodiments of the present disclosure, the second semiconductor layer comprises germanium (Ge), silicon-germanium (SiₓGe₁₋ₓ), germanium-tin (GeₓSn₁₋ₓ) and/or III-V materials, or any combination of these materials.

According to some embodiments of the present disclosure, the second semiconductor layer consists essentially of germanium.

According to some embodiments of the present disclosure, a stress level of the second semiconductor layer is between −5 GPa and +5 GPa.

According to some embodiments, epitaxially growing a III-V material in the trenches to form channel structures of transistors of a first type, comprises growing a III-V material layer or stack comprising e.g. InP, InₓAl₁₋ₓAs, InₓGa₁₋ₓAs, InₓGa₁₋ₓSb, AlₓGa₁₋ₓSb, AlₓGa₁₋ₓSb(As), GaN or any combination thereof.

According to some embodiments of the present disclosure, the dielectric bonding layer comprises or consists essentially of silicon oxide, silicon nitride, aluminium oxide or any combination thereof.

According to some embodiments of the present disclosure, the silicon protrusions have a width smaller than 20 nm, or smaller than 10 nm, or smaller than 3 nm.

According to some embodiments of the present disclosure, removing the silicon protrusions, thereby creating trenches comprises creating trenches with a depth larger than 150% of its width, for instance trenches with a depth of about twice its width, or trenches with a depth larger than twice its width. For instance, for trenches with a width of 20 nm, the depth can be about 40 nm or larger.

According to some embodiments of the present disclosure, the temperature is kept below 600° C.

According to another aspect of the present invention, an associated substrate is disclosed comprising a silicon substrate the surface of which is oriented along the {100} crystal plane; a dielectric bonding layer on top of the surface, and a second semiconductor layer, the second semiconductor layer being bond to the silicon substrate by means of the dielectric bonding layer and having a lattice constant which is different from the lattice constant of the silicon substrate.

According to some embodiments of the present disclosure, the substrate is oriented along the {100} crystal plane and has a <100> notch direction. The substrate is thus a so-called 45-degree (45°) rotated notch substrate.

It is an advantage of the present disclosure that defects are reduced in the active region areas by using the substrate according to the present disclosure.

According to some embodiments of the present disclosure, the second semiconductor layer comprises germanium, silicon-germanium (SiₓGe₁₋ₓ), germanium-tin (GeₓSn₁₋ₓ) and/or III-V materials, or any combination of these materials.

According to some embodiments of the present disclosure, the dielectric bonding layer comprises silicon oxide, silicon nitride, aluminium oxide or any combination thereof.

The substrate can further comprise features corresponding to features described in relation to the method aspects of the present invention, as will be understood by the skilled person.

### BRIEF DESCRIPTION OF THE DRAWINGS

The disclosure will be further elucidated by means of the following description and the appended figures.

FIGS. 1 to 6 schematically illustrate various stages of fabricating a semiconductor device according to embodiments.

### DETAILED DESCRIPTION OF CERTAIN ILLUSTRATIVE EMBODIMENTS

The present disclosure will be described with respect to particular embodiments and with reference to certain drawings but the disclosure is not limited thereto but only by the claims. The drawings described are only schematic and are non-limiting. In the drawings, the size of some of the elements may be exaggerated and not drawn on scale for illustrative purposes. The dimensions and the relative dimensions do not necessarily correspond to actual reductions to practice of the disclosure.

Furthermore, the terms first, second, third and the like in the description and in the claims, are used for distinguishing between similar elements and not necessarily for describing a sequential or chronological order. The terms are interchangeable under appropriate circumstances and the embodiments of the disclosure can operate in other sequences than described or illustrated herein.

Furthermore, the various embodiments, although referred to as “preferred” are to be construed as exemplary manners in which the disclosure may be implemented rather than as limiting the scope of the disclosure.

The term “comprising”, used in the claims, should not be interpreted as being restricted to the elements or steps listed thereafter; it does not exclude other elements or steps. It needs to be interpreted as specifying the presence of the stated features, integers, steps or components as referred to, but does not preclude the presence or addition of one or more other features, integers, steps or components, or groups thereof. Thus, the scope of the expression “a device comprising A and B” should not be limited to devices consisting only of components A and B, rather with respect to the present disclosure, the only enumerated components of the device are A and B, and further the claim should be interpreted as including equivalents of those components.

The present disclosure relates to a method for dual material channel integration on a silicon substrate. Hereby, one of the semiconductor materials is provided essentially defect free, by using a hetero-epitaxial growth.

As used herein, structurally equivalent crystal planes of a crystalline material, e.g., a silicon crystal, is denoted as a family of crystal planes with Miller or Miller-Bravais indices enclosed in braces, {hkl}, which will be understood to include the equivalent planes denoted by parenthesis. For example, a family of crystal planes of a silicon crystal denoted as {100} will be understood to include structurally equivalent planes (100), (010), (001), (100), (010) and (001), where an underlined Miller index indicates a negative Miller index.

In addition, as used herein, structurally equivalent crystal directions of a crystalline material, e.g., a silicon crystal, is denoted as a family of crystal directions with Miller or Miller-Bravais indices enclosed in angular brackets, <hkl>, which will be understood to include the equivalent directions denoted by brackets. For example, a family of crystal directions of a silicon crystal denoted as <100> will be understood to include structurally equivalent directions [100], [010], [001], [100], [010] and [001], where an underlined Miller index indicates a negative Miller index.

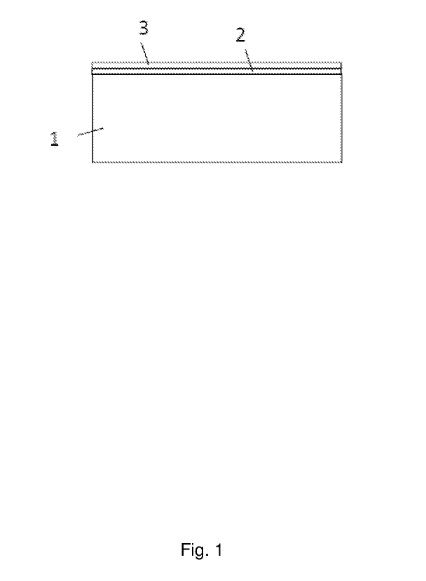

FIG. 1 illustrates a starting substrate comprising a substrate 1 on which various semiconductor devices can subsequently be formed, according to some embodiments. The substrate 1 can include a starting material stack formed thereon, and comprises a silicon substrate (e.g. a silicon wafer), the surface of which is oriented along a {100} crystal plane. The substrate 1 additionally comprises a notch oriented in the <100> direction (also known as a 45-degree)(45° rotated notch silicon substrate). A second semiconductor layer 3 is bonded onto the substrate 1 using an intermediate dielectric bonding layer 2.

Generally in semiconductor processing, a notch can be used to orient the substrate in various process steps that are employed in fabricating the semiconductor devices. In addition to serving this function, in embodiments disclosed herein, using a 45-degree (45°) rotated notch silicon substrate provides an added advantage of trapping defects along the length of a trench that is formed along the <100> direction. As such defects are reduced/avoided in the III-V active areas.

Still referring to FIG. 1, the material of the second semiconductor layer 3 can for instance comprise or essentially consist of germanium (Ge), silicon-germanium (SiₓGe₁₋ₓ), germanium-tin (GeₓSn₁₋ₓ) and/or III-V materials, or any combinations of these materials. As used herein, it will be understood that “essentially consisting of” a material refers to a material whose composition is primarily formed of the material, but may also contain relatively small amounts of other materials that can be incorporated intentionally or unintentionally. For example, a silicon-germanium material may incorporate a relatively small amount of unintentional impurities such as carbon, and/or a relatively small amount of intentional impurities such as dopants. The thicknesses, compositions, and process conditions of the second semiconductor layer 3 and the intermediate bonding layer 2 are chosen such that the second semiconductor has a stress in the range between −5 to +5 GPa. The second channel layer include either a a strained or relaxed Ge layer.

The intermediate dielectric bonding layer 2 can for instance be formed of or comprise silicon oxide, silicon nitride, aluminium oxide or any combination thereof. It can be formed of a suitable dielectric material that allows for a mechanical bonding between the silicon bottom layer and the top material while providing electrical isolation between the substrate 1 and the second semiconductor layer 3.

In the following, the specific substrate described above with respect to FIG. 1 for the first aspect of the present invention can advantageously be used in a method of manufacturing transistor devices comprising III-V materials on a silicon substrate, according to a second aspect of the present invention.

It will be appreciated that the fabrication method above according to a second aspect of the present invention is particularly useful for manufacturing CMOS devices on a silicon substrate, as presented in a third aspect of the present invention. When producing CMOS devices, two different channel materials are used, both channel materials having different lattice constants than silicon and the channel materials respectively being part of transistor devices of different conductivity, for instance being respectively of the NMOS type and PMOS type, on a common silicon substrate.

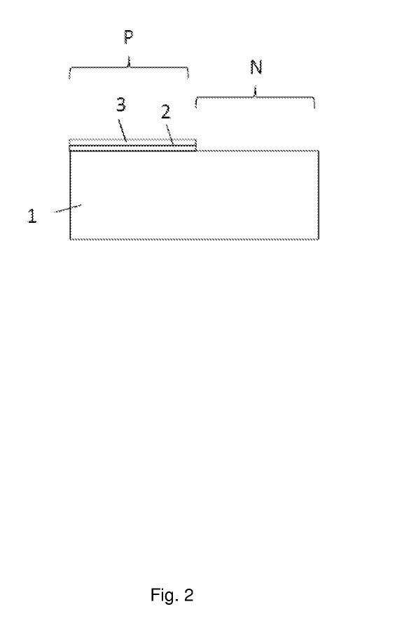

In the following, a fabrication process will be described in detail, whereby the above-described second and third aspects of the present invention are illustrated with respect to FIGS. 2-6.

FIG. 2 represents an intermediate semiconductor structure further illustrating the fabrication process, according to some embodiments. The intermediate semiconductor structure of FIG. 2 is formed by removing a portion of the second semiconductor layer 3 and the dielectric bonding layer 2 to expose the substrate 1 in a first predetermined region (e.g., n-FET region labelled N in FIG. 2) for forming a transistor device of a first type, e.g., an n-FET, while leaving a remaining portion of the second semiconductor layer 3 in a second predetermined region (e.g., p-FET region labelled P in FIG. 2) for forming a transistor device of a second type, e.g., a p-FET. Removing a portion of the second semiconductor layer 3 from first predetermined region (the n-FET region) can be performed by patterning using lithography and etch processes.

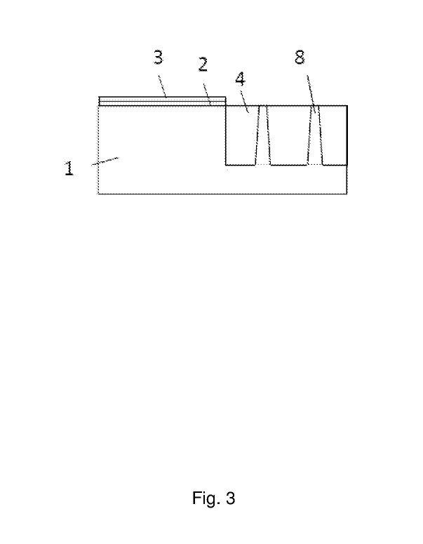

FIG. 3 represents an intermediate semiconductor structure further illustrating the fabrication process, according to some embodiments. The intermediate structure of FIG. 3 is formed by recessing portions of the exposed surface of the substrate 1 of FIG. 2 in the n-FET region and forming a plurality of shallow trench isolation (STI) structures 4 in the recessed portions of the substrate 1. By forming the plurality STI structures 4, a plurality of silicon protrusions 8 extending vertically from a recessed bottom surface of the substrate 1 are formed. The resulting neighbouring protrusions 8 are separated by a STI structure 4. At least some of the silicon protrusions 8 define channel areas of n-FET transistors that are formed in the subsequent processes. In some embodiments, the silicon protrusions 8 have a width smaller than 20 nm and are patterned and isolated in the n-FET region by using a silicon STI process flow.

An STI process flow can include, for instance, comprise or consists the following processes: perform lithography and etching processes to create trenches with silicon areas in between the trenches, the silicon areas corresponding to the protrusions extending from the silicon substrate; filling the created trenches with an insulating material such as for instance a silicon oxide; performing a planarization process as for instance a chemical mechanical polishing (CMP) process for planarizing the surface, resulting in the silicon areas (protrusions) being separated by STI structures 4.

According to some embodiments, one or both of the STI structures and the silicon protrusions 8 have a width smaller than 20 nm, and have a depth greater than 40 nm. Having these dimensions can advantageously allow the benefit of an aspect ratio trapping effect during subsequent epitaxial growth of material of the channel structure in the n-FET region, as will be described below. Preferably, temperature constraints are taken into account, such that the quality of the second semiconductor layer 3 is not compromised during the STI processing. The temperature is therefore preferably kept below 600° C.

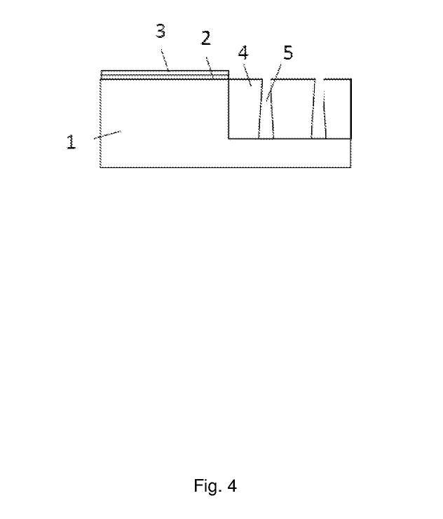

FIG. 4 represents an intermediate semiconductor structure further illustrating the fabrication process, according to some embodiments. After forming the silicon protrusions 8 which extend from a recessed bottom surface of the recessed portion of the starting stack 1 through the adjacent STI structures 4 as described with respect to FIG. 3, method according to the second and third aspects of the present invention comprises at least partially removing the silicon material from the silicon protrusions 8 formed between the STI structures 4, thereby forming trenches 5 between the STI structures 4. In some embodiments, the trenches formed between and through the STI structures 4 have a depth greater than 40 nm in the n-FET region.

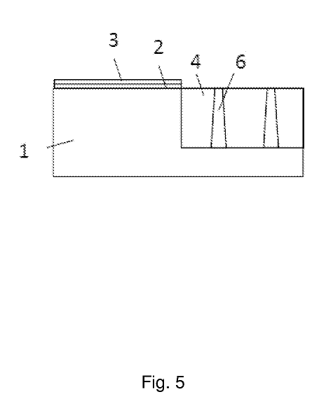

FIG. 5 represents an intermediate semiconductor structure further illustrating the fabrication process, according to some embodiments. After forming the trenches 5 as described above with respect to FIG. 4, the method further includes filling the trenches 5 with a III-V material to form semiconductor channel structures 6. In some embodiments, the semiconductor channel structures 6 correspond to a fin structure of an n-FET transistor. In some embodiments, the semiconductor channel structures 6 are formed by epitaxially growing a III-V channel material. The III-V channel material can include, for instance, a III-V material stack comprising InP, InₓAl₁₋ₓAs, InₓGa₁₋ₓAs, InₓGa₁₋ₓSb, AlₓGa₁₋ₓSb, AlₓGa₁₋ₓSb(As), GaN or any combination thereof, to create a heterostructure stack. Thus formed heterostructure stack can have a lattice constant that is different from the lattice constant of the underlying substrate 1, e.g., {100} silicon substrate. In some embodiments, the trenches 5 cavities can be overfilled or overgrown by growing the channel material such that some of the channel material forms over adjacent STI isolation structures 4, The epitaxially grown material formed over the STI isolation structures 4 can then subsequently be removed, for instance by CMP. Alternatively, the trenches 5 can be filled by the epitaxially grown material without overgrowing the STI area.

The material of the semiconductor channel structure 6 is preferably a crystalline material with a different lattice constant than the lattice constant of the silicon substrate 1.

The inventors have found that the combination of the orientation of the silicon substrate 1 having a {100} crystal plane and a <100> notch direction, limiting the width of the trench 5 to a maximum of 20 nm, and having depth of the trench 5 to exceed 40 nm, (111) oriented facets which are formed during the growth are trapped on or at the trench sidewall. In some embodiments, the trench depth can be about twice the trench width or can be larger than twice the trench width. The depth, width and orientation of the trenches is such that defects generated in the epitaxially grown layer of the material of the semiconductor structure 6 at the substrate portion at the bottom of the trench 5, which propagate in a <111> direction, are trapped by the trench sidewalls. In addition, the inventors have found that limiting the temperature below 600° C. during the growth of the material of the semiconductor channel structure 6 maximizes the crystal quality of the second semiconductor layer 3 during this processing.

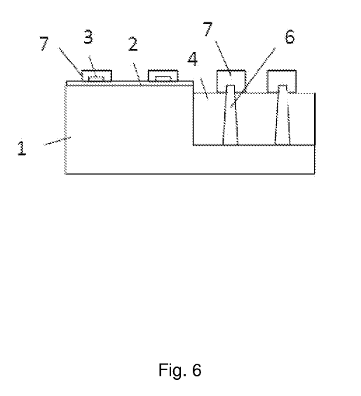

FIG. 6 represents an intermediate semiconductor structure further illustrating the fabrication process, according to some embodiments. In a further step of fabricating a suitable dual channel structure for CMOS device fabrication, the remaining part of the second semiconductor layer 3 is subsequently patterned to provide an appropriate channel structure, for instance a fin structure of a p-FET transistor device, in the p-FET region as depicted in FIG. 2 (labelled P), for the targeted device fabrication using material of the second semiconductor layer 3 as channel or active layer material.

Gate structures 7 can then be provided on the respective semiconductor channel structures, according to processes known to the skilled person.

The skilled person will recognize that temperature constraints apply, as the quality of the channel materials 1 and/or 2 during the above described processing should not be impacted.

As the III-V material is grown on a substrate with a {100} crystal plane and a <100> direction (a 45-degree)(45° rotated notch substrate) there will be no defects along the length of the fin and defects across the width of the trench will be trapped by the STI sidewall. This grown III-V layer may then be used for the high-mobility n-type fin FET.

It will be appreciated by the skilled person that the method and associated substrate of aspects of the present invention allow dual material channel integration on a silicon substrate. Hereby, for instance the III-V material of the semiconductor structures 6, which are preferably channel structures of transistor devices of the n-type, preferably of the fin FET type, can be provided essentially defect free, by using a hetero-epitaxial growth on the silicon substrate with predetermined suitable orientation. At the same time germanium based p-type transistors, preferably of the fin FET type, can be integrated on the same wafer.

The foregoing description details certain embodiments of the invention. It will be appreciated, however, that no matter how detailed the foregoing appears in text, the invention may be practiced in many ways. It should be noted that the use of particular terminology when describing certain features or aspects of the disclosure should not be taken to imply that the terminology is being re-defined herein to be restricted to including any specific characteristics of the features or aspects of the disclosure with which that terminology is associated.

What is claimed is:

1. A method of fabricating a semiconductor device, comprising
providing a substrate comprising a silicon substrate having a main surface oriented in a {100} crystal plane and having a notch oriented in a <100> direction;
forming a plurality of silicon protrusions in a first predetermined region by recessing portions of the main surface surrounding the silicon protrusions;
forming shallow trench isolation (STI) structures adjacent to the silicon protrusions to electrically isolate the silicon protrusions, thereby defining channel areas of a transistor of a first type;
removing at least upper portions of the silicon protrusions, thereby forming trenches between neighboring STI structures; and
filling the trenches with a III-V material.

2. The method of claim 1,
wherein providing the substrate further comprises:
forming a dielectric bonding layer on top of the main surface,
bonding a semiconductor layer on the silicon substrate using the dielectric bonding layer, wherein the semiconductor layer has a lattice constant that is different from a lattice constant of the silicon substrate, and
removing a portion of the semiconductor layer and the dielectric bonding layer to expose the underlying silicon substrate in the first predetermined region for forming the transistor device of the first type, while leaving a remaining portion of the semiconductor layer in a second predetermined region for forming a transistor device of a second type; and
wherein filling the trenches includes epitaxially growing a III-V material in the trenches, thereby forming channel structures of the transistors of the first type that are substantially defect-free; and
wherein the method further comprises patterning the semiconductor layer in the second predetermined region to form channel structures of the transistors of the second type.

3. The method of claim 2, wherein the semiconductor layer comprises a material selected from the group consisting of germanium (Ge), silicon-germanium (SiₓGe₁₋ₓ), germanium-tin (GeₓSn₁₋ₓ) and/or III-V materials a and a combination thereof.

4. The method of claim 3, wherein the semiconductor layer consists essentially of germanium.

5. The method of claim 3, wherein a stress level of the semiconductor layer is between −5 GPa and +5 GPa.

6. The method of claim 2, wherein the channel structures of the transistors of the first type comprise a III-V material layer or stack comprising a material chosen from the group consisting of InP, InₓAl₁₋ₓAs, InₓGa₁₋ₓAs, InₓGa₁₋ₓSb, AlₓGa₁₋ₓSb, AlₓGa₁₋ₓSb(As), GaN and any combination thereof.

7. The method of claim 2, wherein the dielectric bonding layer includes a material chosen from the group consisting of silicon oxide, silicon nitride, aluminum oxide and any combination thereof.

8. The method of claim 2, wherein the silicon protrusions have a width parallel to the main surface that is smaller than 20 nm.

9. The method of claim 1, wherein removing the at least upper portions of the silicon protrusions includes forming trenches having a depth substantially perpendicular to the main surface that is greater than a width of the trenches substantially parallel to the main surface by at least 150%.

10. The method of claim 1, wherein a processing temperature is kept below 600° C.

11. A semiconductor structure comprising:
a substrate comprising a silicon substrate having a surface oriented in a {100} crystal plane and further having a notch oriented in a <100> direction;
a dielectric bonding layer formed on at least a portion of the surface; and
a semiconductor layer bonded to the silicon substrate by the dielectric bonding layer, wherein the semiconductor layer has a lattice constant different from a lattice constant of the silicon substrate.

12. The semiconductor structure of claim 11, wherein the semiconductor layer comprises a material selected from the group consisting of germanium, silicon-germanium (SiₓGe₁₋ₓ), germanium-tin (GeₓSn₁₋ₓ), and a combination thereof.

13. The semiconductor structure of claim 12, wherein the dielectric bonding layer comprises a material chosen from the group consisting of silicon oxide, silicon nitride, aluminum oxide and a combination thereof.

14. The semiconductor structure of claim 13, wherein the substrate further comprises a recessed portion, the recessed portion comprising:
a plurality of protrusions formed in the recessed portion, wherein at least upper portions of the protrusions are formed of a III-V material; and
a plurality of shallow trench isolation (STI) structures formed adjacent to each of the protrusions.

15. The semiconductor structure of claim 14, wherein each of the protrusions extend vertically through at least portions of the adjacent STI structures to form a channel region of an n-channel transistor that protrudes above surfaces of the STI structures.

16. The semiconductor structure of claim 15, wherein the semiconductor layer comprises a patterned channel region of a p-channel transistor.

17. The semiconductor structure of claim 16, wherein at least some of the protrusions are elongated laterally in a direction parallel to the notch in the <100> direction.
